(19) United States
(12) Patent Application Publication
(10) Pub. No.: US 2026/0053014 A1
(43) Pub. Date: Feb. 19, 2026

(54) CONDUCTIVE MATERIALS WITH OPTICAL DEVICE STRUCTURES FOR HYBRID BONDING

(71) Applicant: Adeia Semiconductor Bonding Technologies Inc., San Jose, CA (US)

(72) Inventor: Gaius Gillman Fountain, Jr., Youngsville, NC (US)

(21) Appl. No.: 18/894,549

(22) Filed: Sep. 24, 2024

Related U.S. Application Data
(60) Provisional application No. 63/684,155, filed on Aug. 16, 2024.

(51) Int. Cl. H01L 23/00; H01L 23/15; H01L 23/498; H01L 23/538; H01L 25/16

(52) U.S. Cl. CPC H01L 24/08; H01L 23/15; H01L 23/49838; H01L 23/49872; H01L 23/5385; H01L 24/80; H01L 25/167; H01L 2224/08145; H01L 2224/80895; H01L 2224/80896; H01L 2924/12041

(57) ABSTRACT

A device comprises a first substrate directly hybrid bonded to a second substrate. The first substrate comprises at least one first conductive feature on at least one optical device material stack disposed in a first dielectric layer. The second substrate comprises at least one second conductive feature disposed in a second dielectric layer. A thickness of the at least one first conductive feature is less than about 300 nm, and a thickness of the at least one optical device material stack is greater than about 2 microns.

### CROSS-REFERENCE TO RELATED APPLICATION

The present disclosure claims the benefit of U.S. Provisional Patent Application No. 63/684,155, filed Aug. 16, 2024. The disclosure of which is hereby incorporated by reference herein in its entirety.

### FIELD

The present disclosure relates to systems and methods for hybrid bonding for semiconductor devices and optoelectronic devices.

### BACKGROUND

Indium tin oxide (ITO) is a typical transparent conductor used in light emitting diode (LED) and display applications. Because thicker films of ITO may have more optical absorption in the visible spectrum, it may be desirable to use a thinner film of ITO to have higher transparency in the visible spectrum.

### SUMMARY

Embodiments herein provide for hybrid bonding of thin conductive feature(s) with thicker optical device structure(s). Advantageously, an expansion of the thicker optical structure(s) may enable a surface of the thin conductive feature(s) to contact a corresponding bonding surface and/or apply pressure to a bonding interface during hybrid bonding. The hybrid bonding may enable fine pitch optical devices.

One general aspect includes a device comprising a first substrate directly hybrid bonded to a second substrate. The first substrate includes at least one first conductive feature on at least one optical device material stack disposed in a first dielectric layer, and the second substrate includes at least one second conductive feature disposed in a second dielectric layer. The at least one first conductive feature is less than about 300 nm thick, and the at least one optical device material stack is greater than about 2 microns thick.

In some embodiments, the at least one first conductive feature and the at least one second conductive feature each comprise ITO material. In some embodiments, the thickness of the at least one second conductive feature is less than about 200 nm or less than about 100 nm. In some embodiments, the thickness of the at least one optical device material stack is greater than about 2.5 microns or greater than about 3 microns.

In some embodiments, the at least one optical device material stack includes a plurality of LED material stacks, and a pitch of an array of the plurality of LED material stacks is less than about 10 microns. For example, the pitch may be about one micron, about two microns, less than about 5 microns, or less than about 10 microns. In some embodiments, the second substrate comprises a metal routing line communicatively coupled to the second conductive feature, and the metal routing line is communicatively coupled to a control device.

In some embodiments, the second substrate comprises a glass panel. In some embodiments, the first dielectric layer comprises an oxide material.

Another general aspect includes a method of bonding substrates. The method includes providing a first substrate including at least one first conductive feature on at least one optical device material stack disposed in a first dielectric layer, providing a second substrate comprising at least one second conductive feature disposed in a second dielectric layer, and directly hybrid bonding the first substrate to the second substrate. A thickness of the at least one first conductive feature is less than about 300 nm, and a thickness of the at least one optical device material stack is greater than about 2 microns. In some embodiments, providing the first substrate includes forming the first dielectric layer on the at least one optical device material stack, forming at least one opening in the first dielectric layer to expose a surface of the at least one optical device material stack, and forming the first conductive feature in the opening.

Another general aspect includes a device including a reconstituted substrate directly hybrid bonded to a glass panel. A reconstituted substrate includes a plurality of LEDs disposed in a first dielectric layer on a silicon layer. Each LED includes an LED material stack and a first conductive feature on the LED material stack disposed in the first dielectric layer. A thickness of the LED material stack is greater than about 2 microns. A thickness of the first conductive features is less than about 300 nm. The glass panel includes at least one second conductive feature disposed in a second dielectric layer. In some embodiments, the glass panel comprises at least one metal routing line communicatively coupled to the at least one second conductive feature, and the at least one metal routing line is communicatively coupled to a control device.

### BRIEF DESCRIPTION OF THE DRAWINGS

The above and other objects and advantages of the disclosure will be apparent upon consideration of the following detailed description, taken in conjunction with the accompanying drawings.

FIGS. 1A-1B schematically illustrates a hybrid bonding method, according to some embodiments;

FIG. 2A schematically illustrates a hybrid bonding method, according to some embodiments;

FIG. 2B schematically illustrates a portion of an example display device, according to some embodiments;

FIG. 3 schematically illustrates aspects of a method of preparing a substrate for hybrid bonding, according to some embodiments;

FIG. 4 schematically illustrates an example optical device structure, according to some embodiments; and

FIG. 5 schematically illustrates a top view of a portion of an example display device, according to some embodiments.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

Embodiments herein provide for hybrid bonding with a thin conductive feature over a thicker device structure (e.g., optical device structure). An expansion of the thicker device structure may enable a surface of the thin conductive feature to contact a corresponding bonding surface and/or apply pressure to a bonding interface during hybrid bonding. The hybrid bonding may enable fine pitch optical devices.

As described below, semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” may be used to describe surfaces of material layers or features formed on, in, or through the semiconductor substrate, whether or not the material layers or features are ultimately present in the fabricated or assembled device.

Spatially relative terms are used herein to describe the relationships between elements, such as the relationships between layers and other features described below. Unless the relationship is otherwise defined, terms such as “above,” “over,” “upper,” “upwardly,” “outwardly,” “on,” “below,” “under,” “beneath,” “lower,” and the like are generally made with reference to the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds”. In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds.” In some hybrid bonding embodiments, there are many first conductive features, each directly bonded to a second conductive feature, without any intervening adhesive. In some embodiments, nonconductive features on the first element are directly bonded to nonconductive features of the second element at room temperature without any intervening adhesive, which is followed by bonding of conductive features of the first element directly bonded to conductive features of the second element via annealing at slightly higher temperatures (e.g., >100° C., >200° C., >250° C., >300° C., etc.).

Direct bonding may include direct dielectric bonding techniques as described herein, and may give rise to direct dielectric bonds. Hybrid bonding may include hybrid bonding techniques as described herein, and may give rise to direct hybrid bonds.

Hybrid bonding methods described herein generally include forming conductive features in the dielectric surfaces of the to-be-bonded substrates, activating the surfaces to open chemical bonds in the dielectric material, and terminating the surfaces with a desired species. In some embodiments, activating the surface may weaken chemical bonds in the dielectric material.

Activating and terminating the surfaces with a desired species may include exposing the surfaces to radical species formed in a plasma. In some embodiments, the plasma is formed using a nitrogen-containing gas, e.g., N₂, or forming gas and the terminating species includes nitrogen and hydrogen. In some embodiments, the surfaces may be activated using a wet cleaning process, e.g., by exposing the surfaces to aqueous solutions. In some embodiments, the aqueous solution is tetramethylammonium hydroxide diluted to a certain degree or percentage. In some embodiments, an aqueous solution may be ammonia. In some embodiments, the plasma is formed using a fluorine-containing gas, e.g., fluorine gas or helium containing a small amount of fluorine and/or nitrogen such as about 10% or less by volume, 9% or less, 8% or less, 7% or less, 6% or less, 5% or less, 4% or less, 3% or less, 2% or less, for example 1% or less.

Typically, the hybrid bonding methods further include aligning the substrates, and contacting the activated surfaces to form direct dielectric bonds. After the dielectric bonds are formed, the substrates may be heated to a temperature between 50° C. to 150° C. or more, or of 150° C. or more and maintained at the elevated temperature for a duration of about 1 hour or more, such as between 8 and 24 hours, to form direct metallurgical bonds between the metal features.

As used herein, the term “substrate” means and includes any workpiece, wafer, panel, or article that provides a base material or supporting surface from which or upon which components, elements, devices, assemblies, modules, systems, or features of the devices described herein may be formed. The term substrate also includes display substrates such as glass panels or “semiconductor substrates” that provide a supporting material upon which elements of a semiconductor device are fabricated or attached, and any material layers, features, electronic devices, and/or passive devices formed thereon, therein, or therethrough. For ease of description elements, features, and devices formed therefrom are referred to in the singular or plural but should be understood to describe both singular and plural, e.g., one or more, unless otherwise noted.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564 , filed Jun. 30, 2023, and U.S. patent application Ser. No. 18/391,173 , filed Dec. 20, 2023, the entire contents of each of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact.

In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

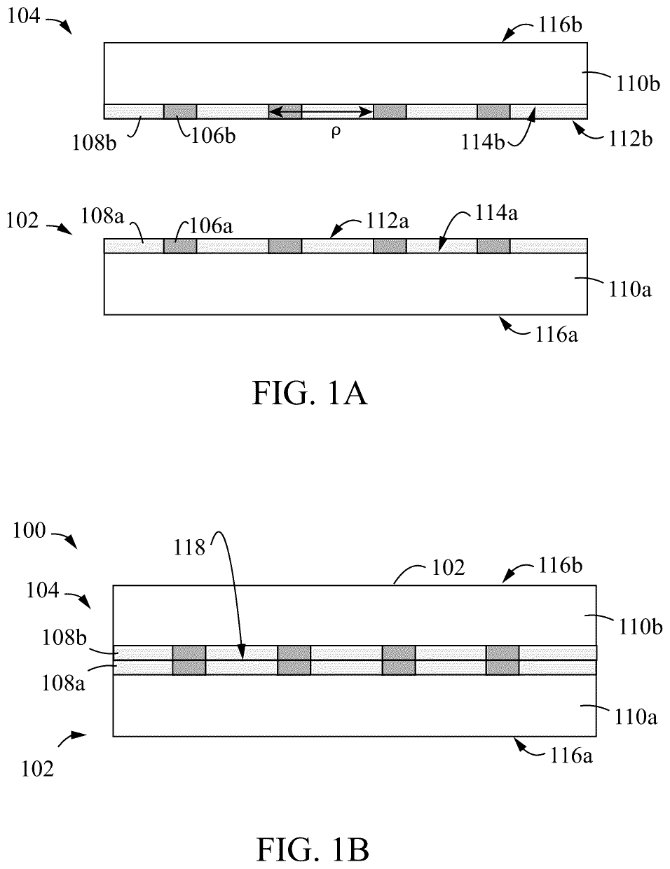

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C..

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO₃) or lithium niobate (LiNbO₃), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes).

Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm.

Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials'melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

Certain implementations disclosed herein relate to optoelectronic devices that include directly bonded contacts comprising optically transparent or optically semi-transparent electrically conducting material (referred to herein collectively as transparent conductors or TCs) instead of metal direct bonded contacts. For example, the optoelectronic devices can include optical elements or devices (e.g., photodiodes; light emitting diodes (LEDs)); quantum dot light emitting diodes (QLEDs); lasers; vertical-cavity surface-emitting lasers (VCSELs); transparency control pixels; liquid crystal pixels; adaptive optics; solar cells; waveguides; spatial light modulators; diode lasers; electrochromic devices) that are stacked on or bonded to one another to form a bonded structure. The TCs on separate substrates can be planarized and the planarized surfaces of the substrates can be placed in contact with one another, as described herein, to form the bonded structures.

In certain implementations, the optoelectronic devices described herein are configured to be used in various contexts which are area-limited (e.g., displays for virtual reality (VR) or augmented reality (AR) applications; multijunction solar cells) or other designs comprising an optoelectronic (e.g., electro-optical) element within a stack of other optical elements, beneficially utilizing the TCs for providing electrical connection between electrical elements while not appreciably blocking light.

As used herein, the term “optically transparent” includes but is not limited to optically translucent, optically semi-transparent, and/or having an optical transmittance of at least 50% (e.g., at least 60%; at least 75%; at least 88%; greater than or equal to 95%) at optical wavelengths in a predetermined range. For example, the predetermined range for optically transparent components (e.g., elements; substrates; layers; devices; features) can be visible wavelengths (e.g., 390 nanometers to 750 nanometers; 400 nanometers to 700 nanometers), ultraviolet wavelengths (e.g., 100 nanometers to 400 nanometers), infrared wavelengths (e.g., 800 nanometers to 1 millimeter), and/or short-wave infrared (SWIR) wavelengths (e.g., 1400 nanometers to 3000 nanometers).

In some embodiments, some electrically conductive oxides (e.g., indium tin oxide or ITO) or nitrides may have the ability to self-bond at modest temperatures (e.g., in a range of 75° C. to 400° C.; in a range of 120° C. to 300° C.; in a range of 150° C. to 300° C.). In certain implementations, use of electrically conductive oxide or nitride layers can simplify processes for bonding (e.g., blanket wafer and hybrid bonding surfaces) by omitting one or more other processing steps (e.g., planarization and/or surface activation). For example, the electrically conductive oxide or nitride layers can be self-leveled if planarized before patterning. In conjunction with certain layout structures, such electrically conductive oxide or nitride layers can be used to bond multiple input/output components with a single material interface. For example, ITO can be used to bond two substrates without a surface activation step, and in certain implementations, without a surface planarization (e.g., chemical-mechanical polishing or CMP) step. The electrically conductive oxide or nitride layers can also allow bonding at modest temperatures (e.g., less than 300° C.) and can be used for surface mounting. In view of the electrical conductivity, such layers can provide electromagnetic shielding for other components of the electronic packages. In addition, because certain such materials are substantially optically transparent, they can be used for bonding optoelectronic applications, as well as in other structures where photon transmission is not a factor.

Conductive materials, transparent conductors, or transparent conductive materials may be used in optical devices or elements. For example, ITO may be a typical conductive material used in LED and display applications. A film of ITO about 300 nm thick may have transparency in a visible spectrum of about 80%. A thicker ITO film may have more optical absorption. Because thicker films of ITO may have more optical absorption in the visible spectrum, it may be desirable to use a thin film of ITO (e.g., less than about 300 nm or less than about 200 nm) to have higher transparency in the visible spectrum.

Some optical device applications may be a heterogeneous system that integrates optical devices and control devices manufactured using different substrates and different process flows. For example, in a display application, an optical device may be an LED, and a control device may be used to control the operation of one or more LEDs. To communicatively couple one or more optical devices to the control device, it may be advantageous to use hybrid bonding for fine pitch applications. However, hybrid bonding may require expansion of a contact material to overcome a recess of the contact material and to generate a bonding force necessary for contact to contact bonding. In some embodiments, a contact is an electrode or pad of an LED, and the contact material is ITO or any suitable transparent conductive material. The electrode or pad of the LED may comprise a thin film of ITO to provide for higher transparency in the visible spectrum. However, it may be difficult to hybrid bond with a thin film of ITO (e.g., as a first conductive feature in a first dielectric layer to a second conductive feature in a second dielectric layer). For example, a thickness of the ITO film may be less than about 300 nm or less than about 200 nm and thermal expansion coefficient may be around 5 or 6, which may make it difficult for the ITO material to expand to overcome a recess of the contact material (e.g., between a first conductive feature and a second conductive feature) and generate a bonding force necessary for the contact to contact bonding (e.g., between the first conductive feature and the second conductive feature).

Forming a thin conductive feature on a thicker optical device material stack may help enable hybrid bonding of the thin conductive feature. For example, hybrid bonding of a first substrate comprising an optical device with a first conductive feature comprising a thin electrode disposed in a first dielectric layer to a second substrate comprising a second conductive feature disposed in a second dielectric layer may be enabled. The second substrate may comprise a control device for controlling operation of the optical device of the first substrate. In some embodiments, the first substrate may comprise a control device for controlling the operation of the optical device of the first substrate. The second substrate may comprise connectors or metal routing to connect to the control device (e.g., either on the first substrate or the second substrate). The thicker optical device material stack may be used as part of an expanding element during hybrid bonding to help overcome a recess of the thin conductive feature (e.g., contact material) and generate a bonding force necessary for the first conductive feature to the second conductive feature (e.g., contact to contact bonding).

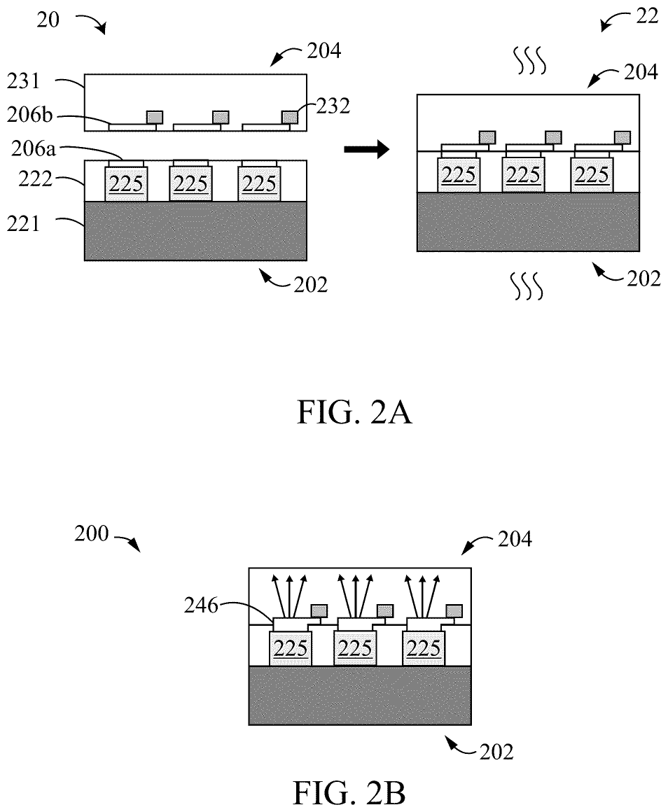

FIG. 2A schematically illustrates a hybrid bonding method, according to some embodiments. In some embodiments, the hybrid bonding method may be used to communicatively couple an optical device to a control device.

At block 20, the method may include providing a first substrate 202 (e.g., first element) and a second substrate 204 (e.g., second element). For example, a first substrate 202 may comprise a plurality of LEDs, and the second substrate 204 may comprise one or more control devices for controlling the plurality of LEDs (e.g., a control device to control one or more LEDs). In some embodiments the first substrate 202 may comprise any suitable optical devices (e.g., a plurality of lasers, photodiodes, solar cells, etc.). In some embodiments, the second substrate 204 may comprise any suitable control devices for controlling the plurality of optical devices (e.g., processors, etc.).

In some embodiments, the first substrate 202 comprises a base layer 221 (e.g., base portion), a first dielectric layer 222, one or more optical device material stacks 225, and one or more first conductive features 206a disposed in the first dielectric layer. The base layer 221 may comprise a silicon material, a semiconductor material, or any suitable material described in the present disclosure. Although three optical device material stacks 225 are shown in FIG. 2A, there may be any suitable number of optical device material stacks (e.g., one, two, three or more, thousands, millions, etc.).

In some embodiments, the one or more first conductive features 206a have a thickness of less than about 300 nm, or less than about 200 nm, or less than about 100 nm, or less than about 50 nm. In some embodiments, the one or more first conductive features 206a (e.g., electrodes or bond pads) comprise a transparent conductive material. The transparent conductive material may be a transparent conductive oxide (TCO) material such as ITO or any suitable TCO (e.g., indium-doped zinc oxide (IZO), tin oxide (SnO₂), etc.). In some embodiments, the conductive material may be optically semi-transparent (e.g., metal or polysilicon layer having a thickness less than 50 nanometers). In some embodiments, one or more first conductive features 206a may comprise any suitable conductive material. Examples of conductive materials include, but are not limited to: copper; tungsten; cobalt; doped and undoped metal oxides; aluminum zinc oxide (AZO); indium tin oxide (ITO, In₂O₃); zinc oxide (ZnO); zinc tin oxide (ZnSnO₃, Zn₂SnO₄); indium-doped zinc oxide (IZO); indium oxide; cadmium tin oxide (Cd₂SnO₄); tin oxide (SnO₂); titanium dioxide (TiO₂); niobium-doped titanium dioxide (Nb—TiO₂); titanium nitride (TiN); tin nitride (Sn₃N₄); other metal nitrides (e.g., A₃N₂ where A=Mg, Zn, Sn); transition metal nitrides comprising a IIIB, IVB, or VB transition metal.

In some embodiments, one or more LEDs (e.g., micro-LEDs) may comprise the one or more optical device material stacks 225. In some embodiments a pitch of the first conductive features 206a may be less than about 10 microns.

In some embodiments, the second substrate 204 comprises one or more second conductive features 206b disposed in a second dielectric layer 231. In some embodiments, the one or more second conductive features 206b comprise ITO routing. The second substrate 204 comprises one or more connectors 232 disposed in the second dielectric layer 231. The one or more connectors 232 (e.g., metal routing lines) may electrically couple the one or more conductive features 206b to one or more control devices. In some embodiments, the connectors 232 comprise metal routing. In some embodiments, the ITO routing (e.g., conductive features 206b) may be combined with metal routing (e.g., connectors 232) to connect to driver circuitry.

In some embodiments, the one or more second conductive features 206b may be similar to the first conductive features. The one or more first conductive features 206a and second conductive features 206b may be a same or different material and/or a same or different thickness. In some embodiments, the first conductive features 206a and the second conductive features 206b each comprise ITO material.

In some embodiments, the second dielectric layer 231 may be similar to the first dielectric layer 222. The second dielectric layer 231 and the first dielectric layer 222 may be a same or different material. In some embodiments, the first dielectric layer 222 and second dielectric layer 231 each comprise an oxide material or any suitable dielectric material described in the present disclosure.

Generally, directly bonding the surfaces (of the dielectric material layers formed on the first and second substrates) includes preparing, aligning, and contacting the surfaces. Examples of dielectric material layers include silicon oxide, silicon nitride, silicon oxynitride, and silicon carbonitride. Preparing the surfaces may include smoothing the respective surfaces to a desired surface roughness, such as between 0.1 to 3.0 nm RMS, activating the surfaces to weaken or open chemical bonds in the dielectric material, and terminating the surfaces with a desired species. Smoothing the surfaces may include polishing the first and second substrates using a CMP process. Activating and terminating the surfaces with a desired species may include exposing the surfaces to radical species formed in a plasma. The bond interface between the bonded dielectric layers can include a higher concentration of materials from the activation and/or last chemical treatment processes compared to the bulk of the bonding layers. For example, some embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In embodiments that utilize an oxygen plasma for activation, an oxygen concentration peak can be formed at the bond interface between non-conductive bonding surfaces.

In some embodiments, the plasma is formed using a nitrogen-containing gas, e.g., N2, and the terminating species includes nitrogen, or nitrogen and hydrogen. In some embodiments, fluorine may also be present within the plasma. In some embodiments, the surfaces may be activated using a wet cleaning process, e.g., by exposing the surfaces to an aqueous ammonia solution. In some embodiments, the dielectric bonds may be formed using a dielectric material layer deposited on only one of the first and second substrates, but not on both. In those embodiments, the direct dielectric bonds may be formed by contacting the deposited dielectric material layer of one of the first and second substrates directly with a bulk material surface (or such a surface with a native oxide) of the other substrate.

At block 22, the method includes hybrid bonding the first substrate 202 and second substrate 204 to form hybrid bonds. The substrates 202 and 204 are aligned and brought in contact with each other. In some embodiments, heat is applied during the hybrid bonding. The applied heat may cause an expansion of the thicker device structure (e.g., optical device material stack 225) to enable a surface of the thin conductive feature(s) (e.g., conductive features 206a) to contact a corresponding bonding surface (e.g., of conductive features 206b) and/or apply pressure to a bonding interface during hybrid bonding The conductive features 206a and 206b may form direct bonds therebetween (e.g., FIG. 2B shows that conductive features 206a and 206b form a direct interconnect 246).

Directly forming direct dielectric bonds between the first and second substrates may include bringing the prepared and aligned surfaces into direct contact at a temperature less than 150° C., such as less than 100° C., for example, less than 30° C., or about room temperature, e.g., between 20° C. and 30° C. Without intending to be bound by theory, in the case of directly bonding surfaces terminated with nitrogen and hydrogen (e.g., NH₂ groups), it is believed that the hydrogen terminating species diffuse from the interfacial bonding surfaces, and chemical bonds are formed between the remaining nitrogen species during the direct bonding process. In some embodiments, the direct bond is strengthened using an anneal process, where the substrates are heated to and maintained at a temperature of greater than about 30° C. and less than about 450° C., for example, greater than about 50° C. and less than about 250° C., or about 150° C. for a duration of about 5 minutes or more, such as about 15 minutes. Typically, the bonds will strengthen over time even without the application of heat. Thus, in some embodiments, the method does not include heating the substrates.

In embodiments where the substrates are bonded using hybrid bonds, the method may further include planarizing or recessing the metal features below the field surface before contacting and bonding the dielectric material layers. After the dielectric bonds are formed, the substrates may be heated to a temperature of 150° C. or more and maintained at the elevated temperature for a duration of about 1 hour or more, such as between 8 and 24 hours, to form direct metallurgical bonds between the metal features.

Suitable direct dielectric and hybrid bonding technologies that may be used to perform aspects of the methods described herein include ZiBond® and DBI®, each of which are commercially available from Adeia, San Jose, CA, USA.

FIG. 2B schematically illustrates a portion of an example display device 200, according to some embodiments. For example, light generated by an LED (e.g., comprising optical device material stack 225) may exit the display device through a transparent electrode (e.g., portion of bonded conductive features or direct interconnect 246) towards a display surface of the display device.

In some embodiments, the first substrate 202 may be a reconstituted substrate. For example, the base layer 221 may be a silicon substrate, and optical device material stack 225 may be singulated LED material stacks transferred from another wafer. In some embodiments, LED material stacks may be directly bonded or directly hybrid bonded to the silicon wafer. For example, wafers or chips from III-V materials may have smaller wafers than silicon. In some embodiments, an array of singulated LEDs (e.g., microLEDs) from a smaller wafers is transferred and bonded to a silicon wafer. For three color display, there may be three separate array transfers of LEDs, one for each color (e.g., red, green, and blue). In some embodiments, there may be any suitable number colors (e.g., 1, 2, 4 or more, etc.) for a display device. Each array of one color of LEDs may be tiled next to another array of another color of LEDs.

In some embodiments the second substrate 204 is a glass panel and comprises control device(s) or the drive circuitry in a peripheral portion of a glass panel or a peripheral portion of a pixel. The connectors 232 (e.g., metal routing) on the glass panel may electrically couple one or more LEDs to a drive circuitry or control device on the glass panel. In some embodiments, the drive circuitry is on the first substrate 202, and connectors 232 (e.g., metal routing) may electrically couple one or more LEDs to drive circuitry or a control device on the first substrate 202. In some embodiments, a blanket layer of ITO may be disposed on top of the LEDs which may be a ground or a return layer (e.g., LEDs may be driven from the back or from a control device on the first substrate).

In some embodiments, the hybrid bonding techniques as disclosed herein may be applied to stacking multiple layers of optical structures. For example, a display device may comprise a plurality of layers of LEDs. In some embodiments, each layer comprise a reconstituted substrate with LEDs of one color. For a three color display, there may be a layer of red LEDs, a layer of blue LEDs, and a layer of green LEDs to be stacked. Each layer may comprise interconnects to enable electrical connections of the different layers to driver circuity which may be disposed on a base layer of the entire stack, a top layer (e.g., glass panel) of the entire stack, or within one or more layers in the stack. Each layer of the stack may be hybrid bonded using one or more aspects of the example method described with respect to FIG. 2A.

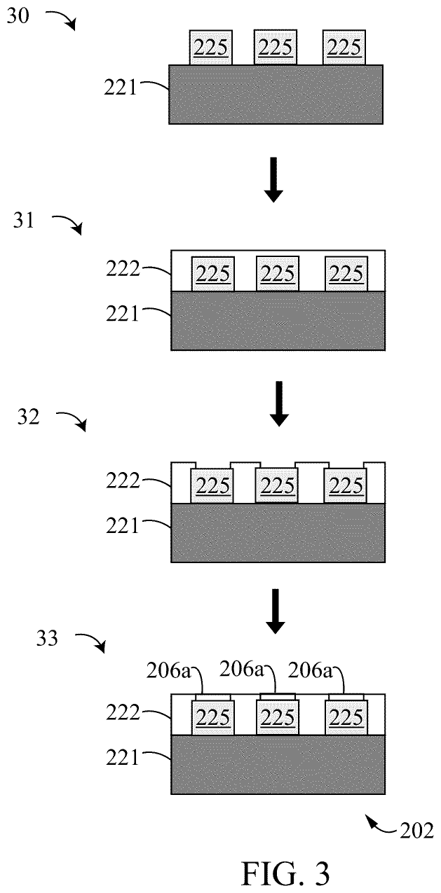

FIG. 3 schematically illustrates aspects of a method of preparing a substrate for hybrid bonding, according to some embodiments.

At block 30, the method comprises providing at least one optical device material stack 225 on a base layer 221. For example, the method may include providing a substrate of at least one mesa-etched micro-LED (e.g., comprising optical device material stack 225) on a silicon wafer (e.g., base layer 221). The method may include mesa-etching micro-LEDs on a silicon wafer. In some embodiments, the base layer 221 may be a substrate providing electrical backside common connection.

At block 31, the method comprises forming a first dielectric layer 222 on the optical device material stack 225. For example, an oxide layer (e.g., first dielectric layer 222) may be deposited on mesa-etched micro-LEDs (e.g., optical device material stack 225) and the deposited oxide layer may be planarized.

At block 32, the method comprises forming at least one opening in the first dielectric layer 222 to expose a surface of the optical device material stack 225. For example, the method may include patterning and etching an oxide layer (e.g., first dielectric layer 222) to expose a surface of at least one micro-LED (e.g., comprising optical device material stack 225).

At block 33, the method comprises forming a conductive feature 206a. The method may include blanket depositing a conductive oxide layer such as ITO and chemically mechanically polishing (CMP) the conductive oxide layer to form pads (e.g., conductive feature 206a) in the opening. For example, an overburden of ITO may be removed during the CMP or polishing process to form the pads (e.g., conductive feature 206a) in the opening. A thickness of the conductive feature 206a may be about 300 nm or less. In some embodiments, the thickness of the conductive feature may be about 200 nm or less, about 100 nm or less, or about 50 nm or less.

In some embodiments, an LED array is D2W or W2W bonded to a glass panel or driver wafer and backside material is removed. The structure may be incorporated into a stacked LED structure for a color display (e.g., a three color display).

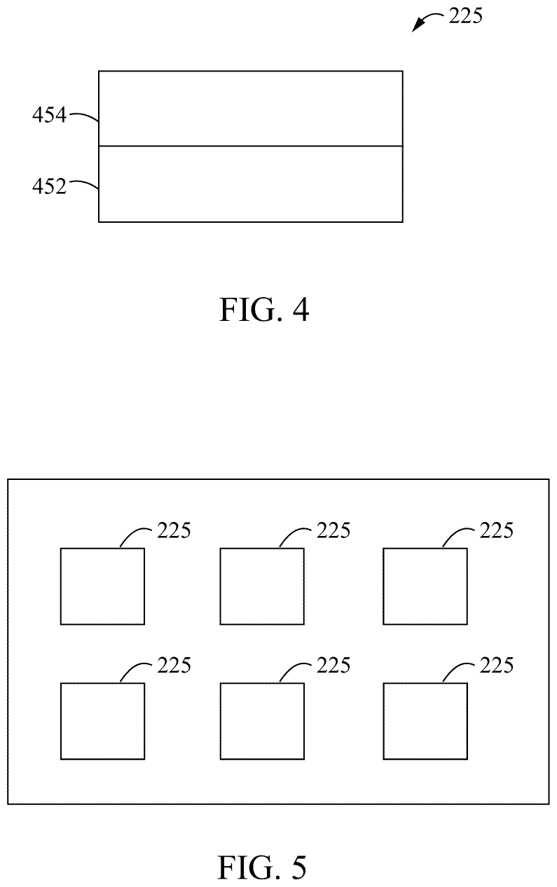

FIG. 4 schematically illustrates an example optical device structure, according to some embodiments. In some embodiments, the optical device material stack 225 comprises a first layer 452 and a second layer 454. An LED may comprise the optical device material stack 225. The first layer 452 may be an n-type layer (e.g., comprising any suitable n-type semiconductor material), and the second layer 454 may be a p-type layer (e.g., comprising any suitable p-type semiconductor materials). Some examples of semiconductor materials are IIIV materials such as GaAs, GaP, and GaN, which may have higher thermal expansion than SiO₂. In some embodiments, the optical device material stack 225 comprises any suitable number of layers (e.g., 1, 3, 4, 5, 6, 7, 8, 9 or more). In some embodiments, the thickness of the optical device structure (e.g., optical device material stack) is greater than about 1 micron, greater than about 1.2 microns, greater than about 2 microns, greater than about 3 microns, greater than about 3.5 microns, or greater than about 4 microns. In some embodiments, the thickness of the optical device structure is about 3.5 microns or about 3.75 microns. In some embodiments, the thickness of the LED structure may be increased in thickness to provide more thermal expansion during annealing to aid in hybrid bonding.

FIG. 5 schematically illustrates a top view of a portion of an example display device, according to some embodiments. The example display device comprises an array of optical device structures 225. In some embodiments, the example display device may be a microLED display device, with pitch in a single digit micron range.

In some embodiments, the present disclosure describes a method of enabling hybrid bonding with thin transparent conductor pads over a thicker LED or other optical device structure. In some embodiments, the bonding technique described in the present disclosure can be used in micro-LED display devices to enable pitches in the single digit micron range, and can facilitate very compact stacked structures. In some embodiments, the hybrid bonding technique described in the present disclosure may enable fine pitch optical devices. For example, the hybrid bonding may enable fine pitch microLED display devices. Fine pitch may be in a single digit micron range, about one micron, about two microns, less than about 5 microns, or less than about 10 microns. In some embodiments, the method and structure described in the present disclosure can have application in miniature display applications.

It is contemplated that any combination of the methods described above may be used to form an optical device or a display device, whether or not expressly recited herein.

The embodiments discussed above are intended to be illustrative and not limiting. One skilled in the art would appreciate that individual aspects of the display and display device, and methods discussed herein may be omitted, modified, combined, and/or rearranged without departing from the scope of the disclosure.

1. A device comprising:
a first substrate comprising at least one first conductive feature on at least one optical device material stack disposed in a first dielectric layer, wherein:
a thickness of the at least one first conductive feature is less than about 300 nm; and
a thickness of the at least one optical device material stack is greater than about 2 microns; and
a second substrate directly hybrid bonded to the first substrate, the second substrate comprising at least one second conductive feature disposed in a second dielectric layer.

2. The device of claim 1, wherein the at least one first conductive feature and the at least one second conductive feature each comprise ITO material.

3. The device of claim 1, wherein the thickness of the at least one first conductive feature is less than about 200 nm.

4. The device of claim 1, wherein the thickness of the at least one first conductive feature is less than about 100 nm.

5. The device of claim 1, wherein the thickness of the at least one optical device material stack is greater than about 2.5 microns.

6. The device of claim 1, wherein the thickness of the at least one optical device material stack is greater than about 3 microns.

7. The device of claim 1, wherein:
the at least one optical device material stack comprises a plurality of LED material stacks; and
a pitch of an array of the plurality of LED material stacks is less than about 10 microns.

8. The device of claim 1, wherein:
the second substrate comprises a metal routing line communicatively coupled to the second conductive feature; and
the metal routing line is communicatively coupled to a control device.

9. The device of claim 1, wherein the second substrate comprises a glass panel.

10. The device of claim 1, wherein the first dielectric layer comprises an oxide material.

11. A method of bonding substrates comprising:
providing a first substrate comprising at least one first conductive feature on at least one optical device material stack disposed in a first dielectric layer, wherein:
a thickness of the at least one first conductive feature is less than about 300 nm; and
a thickness of the at least one optical device material stack is greater than about 2 microns;
providing a second substrate comprising at least one second conductive feature disposed in a second dielectric layer; and
directly hybrid bonding the first substrate to the second substrate.

12. The method of claim 11, wherein:
providing the first substrate comprises:
forming the first dielectric layer on the at least one optical device material stack;
forming at least one opening in the first dielectric layer to expose a surface of the at least one optical device material stack; and
forming the at least one first conductive feature in the opening.

13. The method of claim 11, wherein the at least one first conductive feature and the at least one second conductive feature each comprise ITO material.

14. The method of claim 11, wherein the thickness of the at least one first conductive feature is less than about 200 nm.

15. The method of claim 11, wherein the thickness of the at least one first conductive feature is less than about 100 nm.

16. The method of claim 11, wherein the thickness of the at least one optical device material stack is greater than about 2.5 microns.

17. The method of claim 11, wherein the thickness of the at least one optical device material stack is greater than about 3 microns.

18. The method of claim 11, wherein:
the at least one optical device material stack comprises a plurality of LED material stacks; and
a pitch of an array of the plurality of LED material stacks is less than about 10 microns.

19-21. (canceled)

22. A device comprising:
a reconstituted substrate comprising a plurality of LEDs disposed in a first dielectric layer on a silicon layer, each LED comprising an LED material stack and a first conductive feature on the LED material stack disposed in the first dielectric layer, wherein a thickness of the LED material stack is greater than about 2 microns, and a thickness of the first conductive features is less than about 300 nm; and
a glass panel directly hybrid bonded to the reconstituted substrate, the glass panel comprising at least one second conductive feature disposed in a second dielectric layer.

23. The device of claim 22, wherein:
the glass panel comprises at least one metal routing line communicatively coupled to the at least one second conductive feature; and
the at least one metal routing line is communicatively coupled to at least one control device.
